(19) United States
(12) Patent Application Publication
(10) Pub. No.: US 2026/0059710 A1
(43) Pub. Date: Feb. 26, 2026

(54) LIQUID COOLING DEVICE WITH TWO-PHASE COOLING COMPONENT

(71) Applicant: SHENZHEN APALTEK CO., LTD., Shenzhen (CN)

(72) Inventors: Qineng XIAO, Dongguan (CN); Dagao ZHENG, Shenzhen (CN); Jinjian LIN, Shenzhen (CN)

(21) Appl. No.: 19/004,259

(22) Filed: Dec. 28, 2024

(30) Foreign Application Priority Data
Aug. 23, 2024 (CN) 2024111712520

(51) Int. Cl. H05K 7/20

(52) U.S. Cl. CPC H05K 7/20336; H05K 7/2039

(57) ABSTRACT

A liquid cooling device including a water cooling head, a heat dissipation module, and a two-phase cooling component. The water cooling head includes a base plate and a water cooling shell. An accommodating slot is defined on the water cooling shell. The heat dissipation module includes a heat sink set and a supporting plate. A perforation is defined on the heat sink set. The heat sink set is positioned on the water cooling head. The two-phase cooling component includes an evaporation section and a condensation section. The evaporation section is positioned in the accommodating slot, and the condensation section passes through the perforation. Therefore, the heat dissipation efficiency of the liquid cooling system is improved.

### BACKGROUND OF THE DISCLOSURE

### Technical Field

The technical field relates to a cooling device, and particularly to a cooling device with a two-phase cooling element.

### Description of Related Art

Electronic devices such as central processing units (CPUs) or graphics processing units (GPUs) generate a significant amount of heat during operation. Thus, a cooling circulation system is required to dissipate heat to avoid localized overheating, thereby enhancing the stability and service life of the electronic devices.

Furthermore, using the traditional air-cooled heat dissipation method is relatively difficult for dissipating a large amount of heat to the outside in a short period of time. Therefore, water cooling has been widely used in high-performance electronic devices. Additionally, the water-cooling heat dissipation device includes a water cooling head attached to the heat source for heat exchange, and then conducts the heat through the coolant to the heat sink for dissipation. However, after the water cooling head has been running for a period of time, the temperature of the water cooling head's shell also rises, which in turn leads to a decrease in thermal conductivity efficiency. Therefore, the motivation of the applicant is to find ways to lower the temperature of the water cooling head shell in order to effectively transfer the heat generated by electronic devices and improve cooling efficiency.

In view of the above drawbacks, the inventor proposes this disclosure based on his expert knowledge and elaborate researches in order to solve the problems of related art

### SUMMARY OF THE DISCLOSURE

This disclosure provides a liquid cooling device with a two-phase cooling component to reduce the temperature of the water cooling head, thereby improving the heat dissipation efficiency of the liquid cooling system.

This disclosure is a liquid cooling device including a water cooling head, a heat dissipation module, and a two-phase cooling component. The water cooling head includes a base plate attached to the heat source and a water cooling shell connected to the base plate. An accommodating slot is defined on one side of the water cooling shell and is located perpendicular to the base plate. The heat dissipation module includes a heat sink set and a supporting plate. A perforation is defined on the heat sink set. One end of the supporting plate is connected to the water cooling head, and another end of the supporting plate is connected to the heat sink set. The heat sink set is positioned on one side of the water cooling head through the supporting plate. The two-phase cooling component includes an evaporation section and a condensation section. The evaporation section is positioned in the accommodating slot, and the condensation section passes through the perforation. The water cooling head absorbs heat from the heat source via the base plate and conducts the heat to the water cooling shell, and the heat is then conducted to the evaporation section. A working fluid inside the evaporation section is heated and vaporized, flows to the condensation section, transfers the heat to the heat sink set, condenses back into a liquid state and returns to the evaporation section to complete a thermal cycle.

This disclosure is a liquid cooling device for dissipating a heat from a heat source, the liquid cooling device comprising a water cooling head, a heat dissipation module and a two-phase cooling component. The water cooling head includes a base plate attached to the heat source and a water cooling shell connected to the base plate, wherein an accommodating slot is defined on one side of the base plate. The heat dissipation module includes a heat sink set and a supporting plate, wherein one end of the supporting plate is connected to the water cooling head, and another end of the supporting plate is connected to the heat sink set, and the heat sink set is positioned on one side of the water cooling head through the supporting plate. The two-phase cooling component includes an evaporation section and a condensation section, wherein the evaporation section is positioned in the accommodating slot, and the condensation section is inserted in the heat sink set. The water cooling head absorbs the heat from the heat source via the base plate and conducts the heat to the evaporation section and the water cooling shell, and the heat is conducted to the evaporation section through the water cooling shell; a working fluid inside the evaporation section is heated and vaporized to flow to the condensation section, transfers the heat to the heat sink set through the condensation section, and is condensed back into a liquid state to return to the evaporation section for a thermal cycle.

This disclosure is a liquid cooling device for dissipating a heat from a heat source, the liquid cooling device comprising a water cooling head, a heat dissipation module and a two-phase cooling component. The water cooling head contacts to the heat source. The heat dissipation module includes a heat sink set and disposed in one side of the water cooling head. The two-phase cooling component includes a working fluid. One end of the two-phase cooling component is connected to the water cooling head, and another end of the two-phase cooling component is connected to heat sink set. The water cooling head absorbs the heat and conducts the heat to two-phase cooling component. The working fluid is heated and vaporized, transfers the heat to the heat sink set, and is condensed back into a liquid state to return to the evaporation section for a thermal cycle.

In one embodiment of this disclosure, the liquid cooling device further includes a fixing set. The fixing set is combined with the water cooling head and blocks an outer side of the evaporation section.

In one embodiment of this disclosure, the quantity of the two-phase cooling component, the perforation, the accommodation slot and the fixing set is multiple.

In one embodiment of this disclosure, the fixing set includes a fixing plate and a plurality of fasteners. The fixing plate is combined on the outer side of the accommodating slot through the fasteners.

In one embodiment of this disclosure, the liquid cooling device further includes a water pump disposed in the water cooling head.

In one embodiment of this disclosure, the heat dissipation module further includes a cooling fan integrated on one side of the heat sink set.

In one embodiment of this disclosure, the liquid cooling device further includes a locking set combined on two sides of the water cooling head opposite to each other.

In one embodiment of this disclosure, the number of supporting plate is multiple, and a plurality of supporting plates are combined on one side of the water cooling head to support the heat dissipation module.

In one embodiment of this disclosure, the heat sink set includes a plurality of fins arranged spacedly.

In one embodiment of this disclosure, the two-phase cooling component includes a heat pipe, and a capillary structure is arranged on the inner wall of the heat pipe.

In one embodiment of this disclosure, the base plate and the water cooling shell are stacked and bonded together through vacuum brazing.

In comparison with the related art, the liquid cooling device in this disclosure includes a water cooling head, a heat dissipation module, and a two-phase cooling component. The water cooling head absorbs heat from the heat source and conducts the heat to the two-phase cooling component. Additionally, the working fluid inside the evaporation section is heated and vaporized to flow to the condensation section, transfers the heat to the heat sink set through the condensation section, condenses back into a liquid state, and then returns to the evaporation section to complete the thermal cycle. Thus, the heat is taken away from the water cooling head, thereby achieving cooling of the water cooling head and improving the heat dissipation efficiency of the cooling device.

### BRIEF DESCRIPTION OF THE DRAWINGS

The features of the disclosure believed to be novel are set forth with particularity in the appended claims. The disclosure itself, however, may be best understood by reference to the following detailed description of the disclosure, which describes a number of exemplary embodiments of the disclosure, taken in conjunction with the accompanying drawings, in which:

FIG. 1 and FIG. 2 depict perspective schematic views of the liquid cooling device with a two-phase cooling component from two sides according to this disclosure.

FIG. 3 depicts a perspective exploded schematic view of the liquid cooling device with a two-phase cooling component according to this disclosure.

FIG. 4 depicts a cross-sectional schematic view of the liquid cooling device according to this disclosure.

FIG. 5 depicts a partially enlarged schematic view of FIG. 4.

FIG. 6 depicts a cross-sectional view of the combination of the water cooling head and a two-phase cooling element according to this disclosure.

FIG. 7 depicts a schematic view illustrating the operation of the liquid cooling device according to this disclosure.

FIG. 8 depicts another embodiment of the liquid cooling device according to this disclosure.

FIG. 9 depicts still another embodiment of the liquid cooling device according to this disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

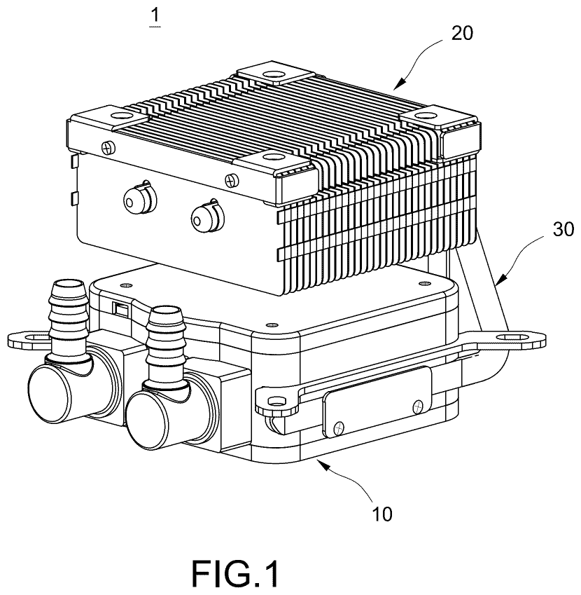

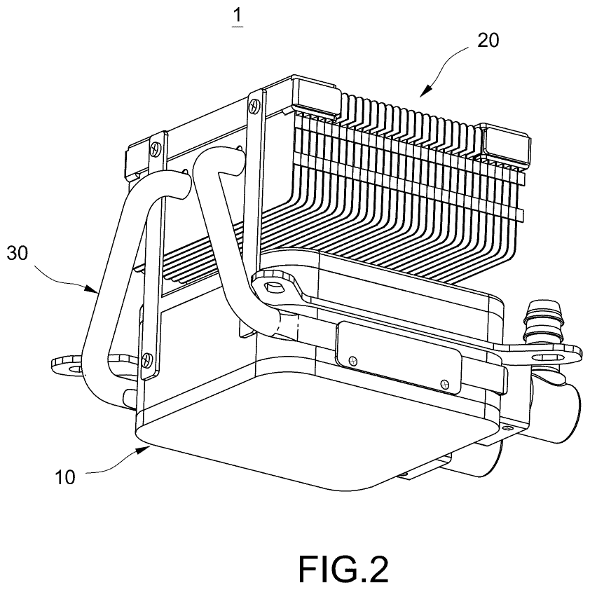

Please refer to FIG. 1 and FIG. 2, which depict perspective schematic views of the liquid cooling device from two sides according to this disclosure. This disclosure is a liquid cooling device 1 including a water cooling head 10, a heat dissipation module 20, and a two-phase cooling component 30. The two-phase cooling component 30 is attached to the cooling shell of the water cooling head 10 and passes through the heat dissipation module 20. Additionally, the two-phase cooling component 40 absorbs the heat from the water cooling head 10 and conducts the heat to the heat dissipation module 20. Accordingly, the heat is taken away and dissipated by the water cooling head 10 through the two-phase cooling component 30, thereby improving heat dissipation efficiency. A more detailed description of the liquid cooling device 1 is as follows.

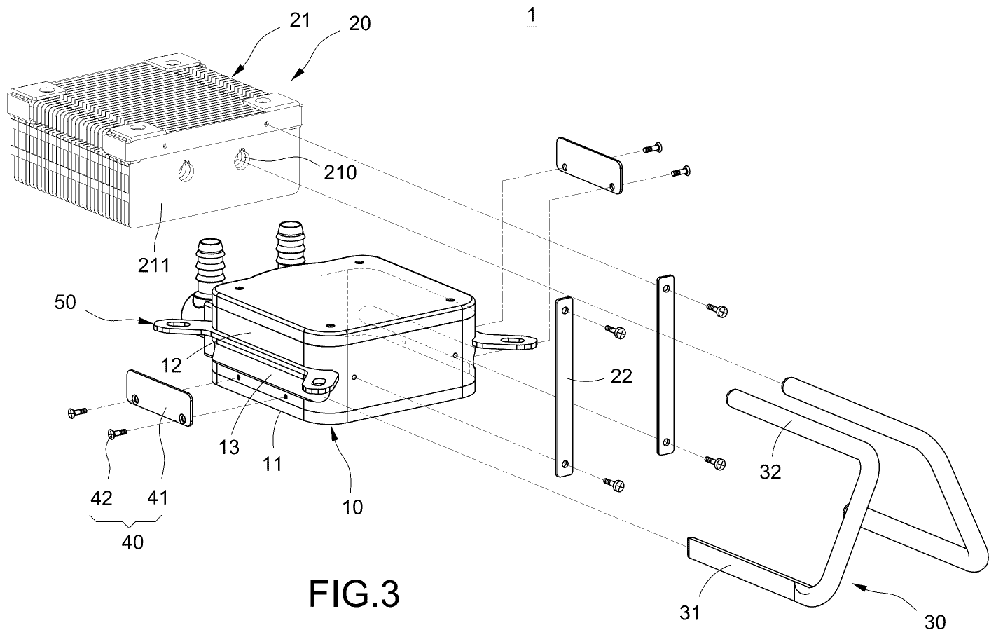

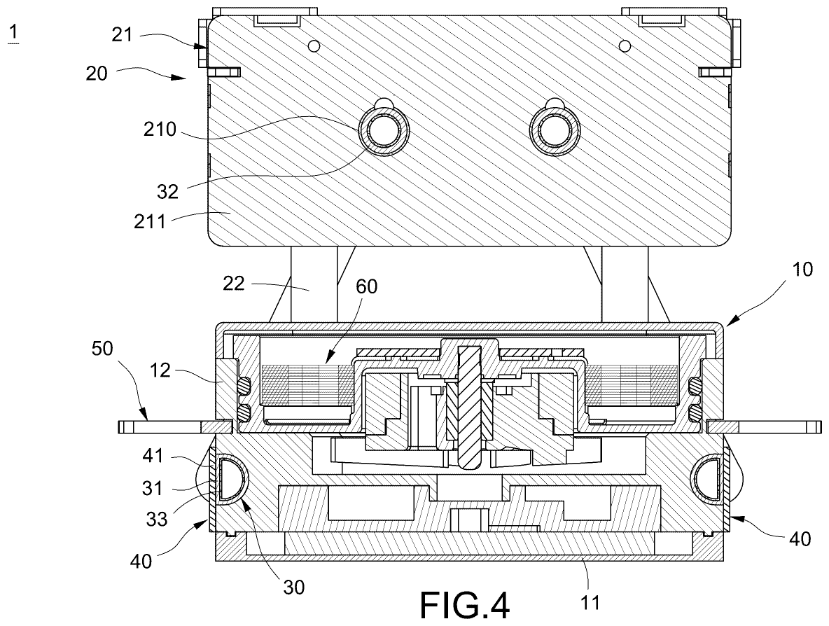

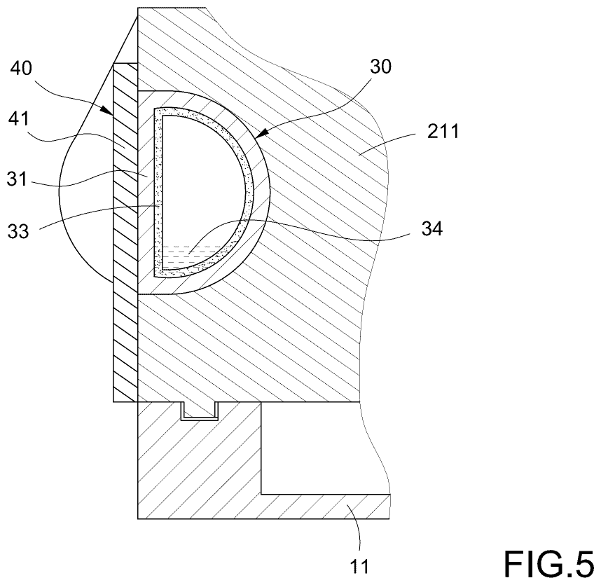

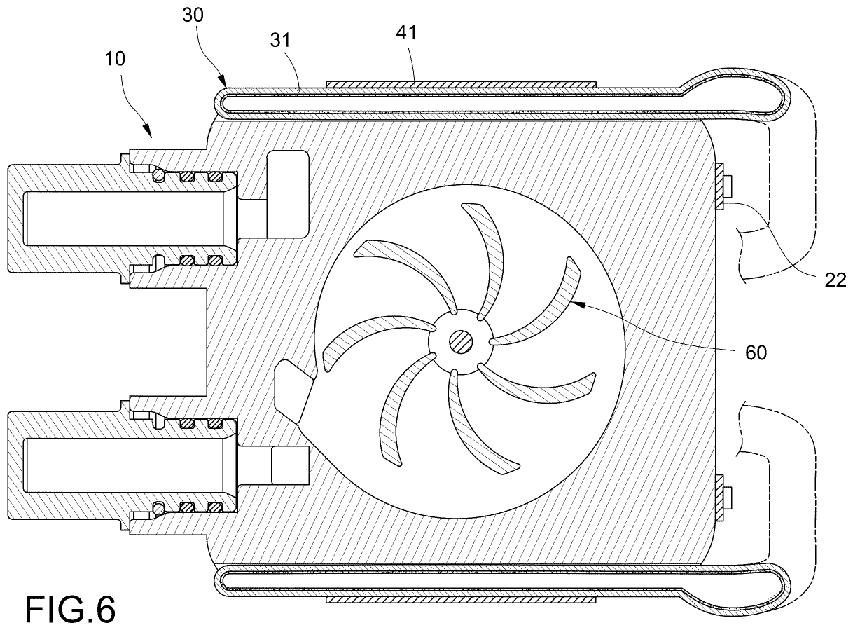

Please further refer to FIG. 3 to FIG. 6, which depict a perspective exploded schematic view of the liquid cooling device with a two-phase cooling component, a cross-sectional schematic view of the liquid cooling device, a partially enlarged schematic view of the liquid cooling device, and a cross-sectional view of the combination of the water cooling head and a two-phase cooling element according to this disclosure. The water cooling head 10 of the liquid cooling device 1 includes a base plate 11 and a water cooling shell 12 adjacent to the base plate 11. An accommodating slot 13 is defined on one side of the water cooling shell 12 and is located perpendicular to the base plate 11. Additionally, the heat dissipation module 20 includes a heat sink set 21 and a supporting plate 22. At least one perforation 210 is defined on the heat sink set 21. In some embodiments, two perforations 210 are disposed on the heat sink set 21. One end of the supporting plate 22 is connected to the water cooling head 10, and the other end of the supporting plate 22 is connected to the heat sink set 21. The heat sink set is supported and positioned on one side of the water cooling head 10 through the supporting plate 22.

It is worth noticing that the base plate 11 and the water cooling shell 12 are made of metal. In some embodiments, the base plate 11 and the water cooling shell 12 are made of a copper alloy and have better thermal conductivity. Additionally, the base plate 11 and the water cooling shell 12 are stacked and bonded together through vacuum brazing. Accordingly, the water cooling head 10 may be mass-produced and has better thermal conductivity.

It should be noted that the heat transfer path of the liquid cooling device 1 in this disclosure is as follows: the adsorbed heat is transferred to the water-cooling shell 12 via the base plate 11 through heat conduction by adhering to the water-cooling shell 12. Then, the phase change is performed through the evaporation section 31 of the two-phase cooling component 30 for heat transfer.

In this embodiment, the heat sink set 21 includes a plurality of fins 211 arranged spacedly. Additionally, the number of supporting plate 22 is multiple. A plurality of supporting plates 22 are combined on one side of the water cooling head 10 to support the heat dissipation module 20.

Furthermore, the two-phase cooling component 30 includes an evaporation section 31 and a condensation section 32. The evaporation section 31 is positioned in the accommodating slot 13, and the condensation section 32 passes through the perforation 210 of the heat sink set 21. Accordingly, the water cooling head 10 and the heat sink set 21 achieve thermal conduction through the two-phase cooling element 30. In this embodiment, the two-phase cooling element 30 is adapted to configure a U-shaped heat pipe, and a capillary structure 33 is disposed on the inner wall surface of the two-phase cooling element 30. Furthermore, an outer side of the evaporation section 31 is configured to a flat surface, and the inner side of the evaporation section 31 has an outline corresponding to the accommodating slot 13, so that the evaporation section 31 may better adhere to the accommodating slot 13 to improve heat conduction efficiency. In some embodiments, the inner surface of the evaporation section 31 and the accommodating slot 13 may be configured as, but are not limited to, a semicircular arc shape.

It should be noted that a working fluid 34 is filled inside the two-phase cooling component 30. The working fluid 34 absorbs heat to be vaporized in the evaporation section 31, and flows to the condensation section 32. Then, the heat is conducted to the heat sink set 21 through the condensation section 32 and is dissipated through the heat sink set 21. Additionally, the vapor condenses back into a liquid state after releasing heat in the condensation section 32 and then returns to the evaporation section 31 through the capillary structure 33. Thus, the working fluid 34 completes a thermal cycle in this way to achieve heat conduction.

In this embodiment, the liquid cooling device 1 further includes a fixing set 40 and a locking set 50. The fixing set 40 is combined with the water cooling head 10 and blocks the outer side of the evaporation section 31 of the two-phase cooling component 30 to ensure that the evaporation section 31 does not detach from the accommodating slot 13. Specifically, the fixing set 40 includes a fixing plate 41 and a plurality of fasteners 42. The fixing plate 41 is combined on the outer side of the accommodating slot 13 through the fasteners 42. Additionally, the locking set 50 is composed of two locking components, and the locking components are respectively coupled to two sides of the water cooling head 10 opposite to each other to secure the liquid cooling device 1 in a fixed position.

It is worth noticing that the liquid cooling device 1 further includes a water pump 60. The water pump 60 is installed inside the water cooling head 10 to increase the water pressure within the water cooling head 10 and enhance the water flow speed inside the water cooling head 10. Moreover, the two-phase cooling component 30, the perforation 210, the accommodation slot 13, and the fixing set 40 are multiple in quantity, respectively. As shown in FIG. 1 and FIG. 2, the two-phase cooling component 30 and the accommodation slot 13 are arranged on two sides of the water cooling head 10 opposite to each other and located below the locking set 50. However, this is not a limitation and may be adjusted based on needs.

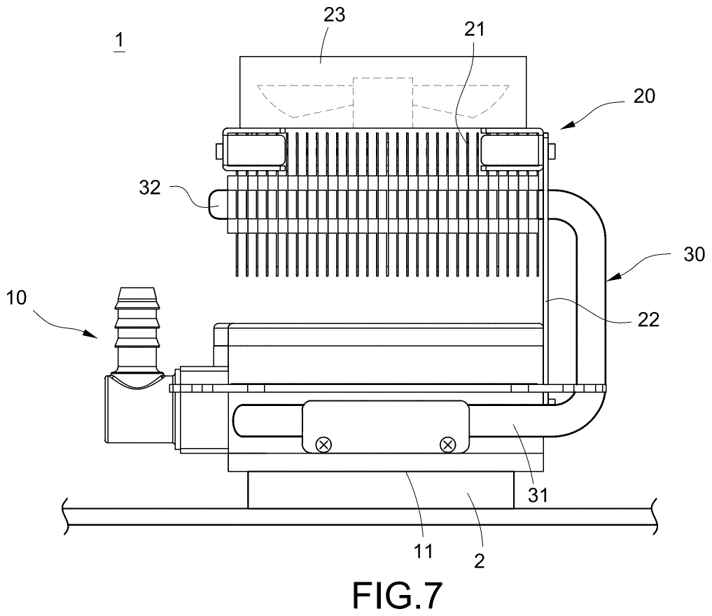

Please further refer to FIG. 7, which depicts a schematic view illustrating the operation of the liquid cooling device according to this disclosure. The liquid cooling device 1 of this disclosure is used for dissipating heat from a heat source 2, such as the computer's central processing unit (CPU) or graphics card (GPU). In some embodiments, the base plate 11 of the water cooling head 10 is attached to the heat source 2. Additionally, the heat dissipation module 20 of the liquid cooling device 1 may further include a cooling fan 23. The cooling fan 23 is integrated (combined) on one side of the heat sink set 21 to take away the heat from the heat sink set 21 by forced convection.

Further, the water cooling head 10 absorbs heat from the heat source 2 via the base plate 11 and conducts the heat to the water cooling shell 12 through the base plate 11 being attached to the water cooling shell 12. Then, the heat is transferred to the evaporation section 31 of the two-phase cooling component 30 through the water cooling shell 12. Additionally, the working fluid 34 inside the evaporation section 31 is heated and vaporized to flow to the condensation section 32, transfers the heat to the heat sink set 21 through the condensation section 32 to be condensed back into a liquid state, and then returns to the evaporation section 31 to complete a thermal cycle.

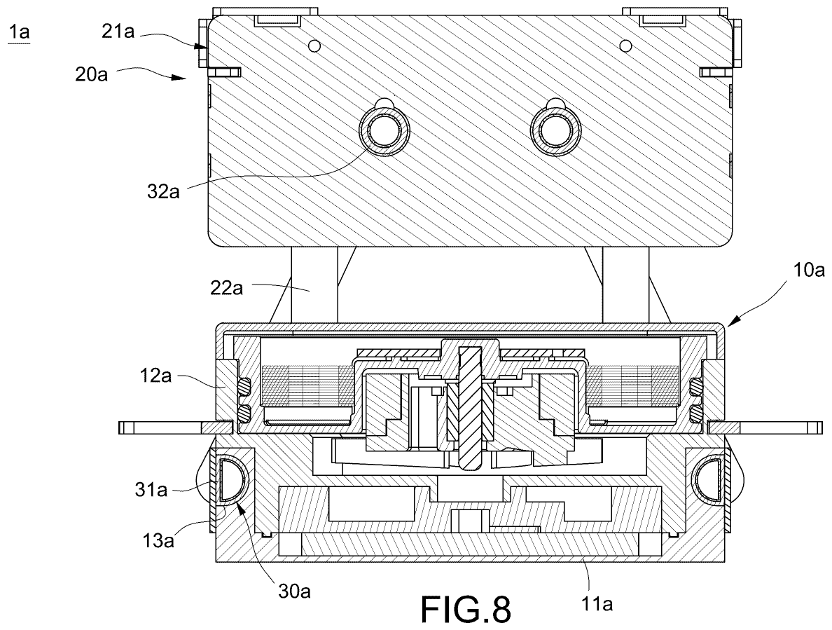

Please refer to FIG. 8, which depict another embodiment of the liquid cooling device according to this disclosure. A liquid cooling device 1a of this disclosure includes a water cooling head 10a, a heat dissipation module 20a, and a two-phase cooling component 30a. The water cooling head 10a includes a base plate 11a and a water cooling shell 12a. The heat dissipation module 20a includes a heat sink set 21a and a supporting plate 22a. The heat sink set 21a is positioned on one side of the water cooling head 10a through the supporting plate 22a.

The difference of this embodiment compared to the previous embodiment lies in the placement of the two-phase cooling component 30a. Specifically, an accommodating slot 13a is defined on one side of the base plate 11a. The two-phase cooling component 30a includes an evaporation section 31a and a condensation section 32a. The evaporation section 31a is positioned in the accommodating slot 13a, and the condensation section 32a is inserted in the heat sink set 21a.

In some embodiments, the base plate 11a of the water cooling head 10a attaches to the heat source. The water cooling head 10a absorbs the heat from the heat source via the base plate 11a and conducts the heat to the evaporation section 31a and the water cooling shell 12a. Additionally, the working fluid inside the evaporation section 31a is heated and vaporized to flow to the condensation section 32a, transfers the heat to the heat sink set 21a through the condensation section 32a, and is condensed back into the liquid state to return to the evaporation section 31a for a thermal cycle.

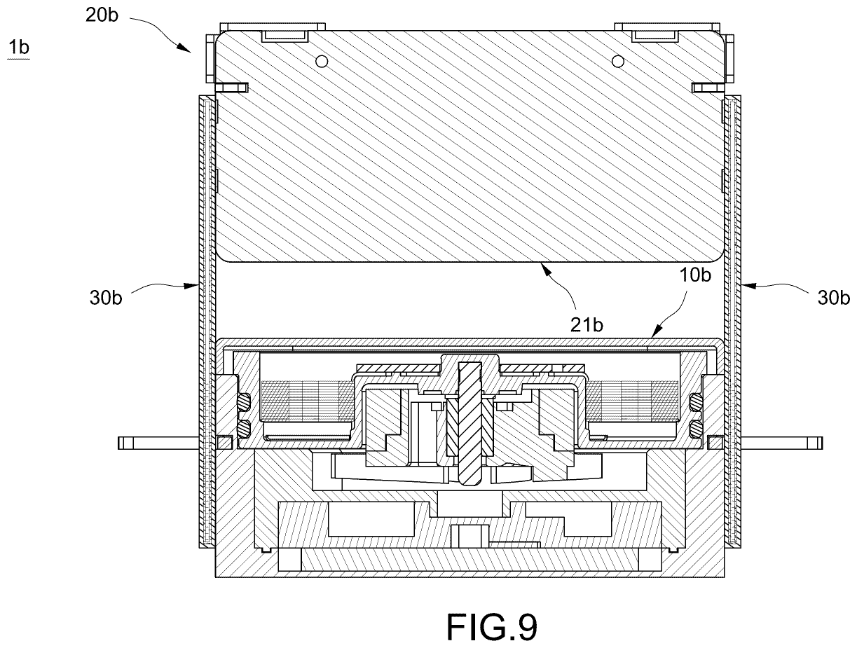

Please refer to FIG. 9, which depict still another embodiment of the liquid cooling device according to this disclosure. A liquid cooling device 1b of this disclosure includes a water cooling head 10b, a heat dissipation module 20b, and a two-phase cooling component 30b. In this embodiment, the water cooling head 10b contacts to the heat source. The heat dissipation module 20b includes a heat sink set 21b and is arranged on one side of the water cooling head 10b spacedly. Additionally, the two-phase cooling component 30b includes a vapor chamber and has a working fluid. One end of the two-phase cooling component 30b is connected to the water cooling head 10b, and another end of the two-phase cooling component 30b is connected to heat sink set 21b. Therefore, the water cooling head 10b absorbs the heat and conducts the heat to two-phase cooling component 30b. The working fluid in the two-phase cooling component 30b is heated and vaporized, transfers the heat to the heat sink set 21b, and is condensed back into a liquid state for a thermal cycle.

While this disclosure has been described by means of specific embodiments, numerous modifications and variations may be made thereto by those skilled in the art without departing from the scope and spirit of this disclosure set forth in the claims.

What is claimed is:

1. A liquid cooling device for dissipating a heat from a heat source, the liquid cooling device comprising:
a water cooling head, comprising a base plate attached to the heat source and a water cooling shell connected to the base plate, wherein an accommodating slot is defined on one side of the water cooling shell perpendicular to the base plate;
a heat dissipation module, comprising a heat sink set and a supporting plate, wherein a perforation is defined on the heat sink set, one end of the supporting plate is connected to the water cooling head, and another end of the supporting plate is connected to the heat sink set, and the heat sink set is positioned on one side of the water cooling head through the supporting plate; and
a two-phase cooling component, comprising an evaporation section and a condensation section, wherein the evaporation section is positioned in the accommodating slot, and the condensation section passes through the perforation;
wherein the water cooling head absorbs the heat from the heat source via the base plate and conducts the heat to the water cooling shell, and the heat is conducted to the evaporation section through the water cooling shell; a working fluid inside the evaporation section is heated and vaporized to flow to the condensation section, transfers the heat to the heat sink set through the condensation section, and is condensed back into a liquid state to return to the evaporation section for a thermal cycle.

2. The liquid cooling device according to claim 1, further comprising a fixing set, wherein the fixing set is combined with the water cooling head and blocks an outer side of the evaporation section.

3. The liquid cooling device according to claim 2, wherein a quantity of the two-phase cooling component, a quantity of the perforation, a quantity of the accommodation slot, and a quantity of the fixing set are all multiple.

4. The liquid cooling device according to claim 2, wherein the fixing set comprises a fixing plate and a plurality of fasteners, and the fixing plate is combined on an outer side of the accommodating slot through the fasteners.

5. The liquid cooling device according to claim 1, further comprising a water pump disposed in the water cooling head.

6. The liquid cooling device according to claim 1, wherein the heat dissipation module further comprises a cooling fan combined on one side of the heat sink set.

7. The liquid cooling device according to claim 1, further comprising a locking set, wherein the locking set is combined on two sides of the water cooling head opposite to each other.

8. The liquid cooling device according to claim 1, wherein a number of the supporting plate is multiple, and a plurality of supporting plates are combined on one side of the water cooling head to support the heat dissipation module.

9. The liquid cooling device according to claim 1, wherein the heat sink set comprises a plurality of fins arranged spacedly.

10. The liquid cooling device according to claim 1, wherein the two-phase cooling component comprises a heat pipe, and a capillary structure is arranged on an inner wall of the heat pipe.

11. The liquid cooling device according to claim 1, wherein the base plate and the water cooling shell are made of metal.

12. The liquid cooling device according to claim 1, wherein the base plate and the water cooling shell are stacked and bonded together through vacuum brazing.

13. A liquid cooling device for dissipating a heat from a heat source, the liquid cooling device comprising:
a water cooling head, comprising a base plate attached to the heat source and a water cooling shell connected to the base plate, wherein an accommodating slot is defined on one side of the base plate;
a heat dissipation module, comprising a heat sink set and a supporting plate, wherein one end of the supporting plate is connected to the water cooling head, and another end of the supporting plate is connected to the heat sink set, and the heat sink set is positioned on one side of the water cooling head through the supporting plate; and
a two-phase cooling component, comprising an evaporation section and a condensation section, wherein the evaporation section is positioned in the accommodating slot, and the condensation section is inserted in the heat sink set;
wherein the water cooling head absorbs the heat from the heat source via the base plate and conducts the heat to the evaporation section and the water cooling shell, and the heat is conducted to the evaporation section through the water cooling shell; a working fluid inside the evaporation section is heated and vaporized to flow to the condensation section, transfers the heat to the heat sink set through the condensation section, and is condensed back into a liquid state to return to the evaporation section for a thermal cycle.

14. A liquid cooling device for dissipating a heat from a heat source, the liquid cooling device comprising:
a water cooling head, contacting to the heat source;
a heat dissipation module, comprising a heat sink set and disposed in one side of the water cooling head; and
a two-phase cooling component, comprising a working fluid, wherein one end of the two-phase cooling component is connected to the water cooling head, and another end of the two-phase cooling component is connected to heat sink set;
wherein the water cooling head absorbs the heat and conducts the heat to two-phase cooling component, the working fluid is heated and vaporized, transfers the heat to the heat sink set, and is condensed back into a liquid state to return to the evaporation section for a thermal cycle.
